(19) United States
(12) Patent Application Publication
(10) Pub. No.: US 2015/0372170 A1
(43) Pub. Date: Dec. 24, 2015

(54) METHOD AND DEVICE FOR PRODUCING A SELECTIVE EMITTER STRUCTURE FOR A SOLAR CELL, SOLAR CELL

(71) Applicant: ASYS AUTOMATISIERUNGSSYSTEME GMBH, Dornstadt (DE)

(72) Inventor: Harald WANKA, Blaustein (DE)

(73) Assignee: ASYS AUTOMATISIERUNGSSYSTEME GMBH, Dornstadt (DE)

(21) Appl. No.: 14/766,597

(22) PCT Filed: Feb. 5, 2014
(86) PCT No.: PCT/EP2014/052242

§ 371 Date: Aug. 7, 2015

(30) Foreign Application Priority Data
Feb. 8, 2013 (DE) 10 2013 202 067.8

(51) Int. Cl. H01L 31/0224; H01L 31/18

(52) U.S. Cl. CPC H01L 31/022433; H01L 31/18

(57) ABSTRACT

The invention relates to a method for producing a selective emitter structure (8) on a useful side (3) of a solar cell (1), wherein the emitter structure (8) comprises a doped emitter layer (4) and several contact elements (5), in particular contact fingers, arranged on the emitter layer, and wherein the emitter layer (4) is provided with higher doping in the region below the contact elements (5) than in the region between the contact elements (5). The following steps are provided: a) providing the solar cell (1) having an emitter layer that is doped overall, b) producing the contact elements (5) on the emitter layer (4), and c) reducing the doping of the emitter layer (4) in the region between the contact elements (5) by an etching processing of the entire useful side (3) of the solar cell (1). The invention further relates to a device and a solar cell.

The invention relates to a method for producing a selective emitter structure on a useful side of a solar cell, wherein the emitter structure comprises a doped emitter layer and several contact elements, in particular contact fingers, arranged on the emitter layer, and wherein the emitter layer is provided with higher doping in the region below the contact elements than in the region between the contact elements.

The invention further relates to a device for implementing the method as well as a corresponding solar cell.

Methods and devices of the aforementioned type are known from the prior art. In order to use the accumulated energy of solar cells, it is known to provide a selective emitter structure on the useful side of the solar cell. This is usually characterized by an emitter layer, which is doped for example with phosphorus, wherein the height or degree of doping varies. In regions of in particular silver-containing contact elements, such as contact fingers, which are provided on the useful side, the emitter layer has a higher doping than in the regions between the contact fingers, so that the energy generated by exposure to the sun's rays can be efficiently extracted by the contacts. The construction of such structures is known in principle.

Generally, several methods are known to produce such emitter structures: In the so-called Schmid process, the emitter layer is partially etched by means of an etching mask before the contacts are applied, in order to selectively reduce the doping before applying the contacts. It is also known to apply an etching paste in the region between the subsequent contacts, or to provide a higher doping in the emitter layer in the region of the subsequent contacts by means of laser radiation, for example.

The known technologies have in common, however, that they require an additional adjustment step, in which the doping process must be adjusted with regard to the production of the contacts so that during subsequent application of the contact elements, these lie on the desired regions of the emitter layer having the higher doping. This adjustment also entails the risk of maladjustment or accidental rotation by 90° of the solar cells or wafers. This leads in both cases to a loss of efficiency of the solar cell, which should be avoided. In order to maintain a tolerance, the region of higher doping is frequently designed significantly wider than the actual contact element in order to avoid misalignment, whereby the efficiency potential of the solar cell is wasted.

A method for producing an elective emitter structure is already known from patent U.S. Pat. No. 5,871,591 A, in which the doping of an emitter layer is reduced in the region between contact elements by means of etching, and a nitride layer is provided.

The object of the invention is to provide a method and a solar cell which ensures in a simple and cost-effective manner a secure electrical contact of the contact elements.

The object of the invention is achieved by means of a method having the features of claim 1. The method according to the invention has the advantage that an adjustment of the contact elements to the regions with higher doping does not occur. Rather, a self-adjustment of the selective emitter structure takes place. Firstly, the adjustment step is thereby saved, and secondly, it is ensured that the region with higher doping need not be overdimensioned in comparison with the contact elements, so that the efficiency of the solar cell is optimally utilized. It is hereby provided according to the invention that in a first step a) the solar cell or a subsequent solar cell-forming wafer, in particular of crystalline silicon, is provided with an overall particularly uniformly and preferably highly doped emitter layer. The emitter layer is thus in total so highly doped across its entire extent that the emitter layer has overall the same (high) doping. It preferably extends across the entire wafer. In a subsequent step b) the contact elements are produced on the emitter layer. For this purpose is selectively applied, for example, a silver paste on the useful side of the solar cell or the emitter layer in the form of the desired contact elements. The contact elements are preferably formed as contact fingers which extend parallel to each other across the solar cell. Then in a step c) the doping of the emitter layer is reduced in the region between the contact elements by an etching processing of the entire useful side of the solar cell. It is therefore provided that in step c) the entire useful side of the solar cell, with the contact elements already present thereon, undergoes an etching processing. The contact elements themselves are thus also exposed to the etching process. However, as they rest on the emitter layer, the etching processing affects only the contact elements as well as the emitter layer between the contact elements. The doping is thereby reduced in the region between the contact elements, while the doping below the contact elements remains. The contact elements themselves thus form an etching mask for the emitter layer.

The etching preferably occurs wet-chemically. Alternatively, the etching is preferably carried out by plasma exposure or etching gases. Such etching processes are generally known, thus these need not be discussed in detail. It is important according to the invention that the etching processes take place after the application of the contact elements on the emitter layer.

According to an advantageous development of the invention, it is provided that in particular the height of the contact elements is selected depending on the desired reduction in the doping in the emitter layer. It can thereby be ensured that, in spite of the etching process, enough material of the contact elements is available in order to optimally carry away the generated energy.

According to the invention, it is provided that after step c) in a following step d) at least the useful side of the solar cell is provided with a nitride layer. The nitride layer serves as an anti-reflective layer, which ensures that the highest possible proportion of the solar energy is introduced into the solar cell or into the wafer and the emitter layer.

The nitride layer is preferably generated in step d) by means of nitride deposition. In particular, it is provided that a nitride layer of approximately 70 to 100 nm is deposited. This nitride layer thus also covers the contact elements.

According to the invention, it is provided that after step d) in a following step e) at least one busbar is produced which, in order to electrically connect at least some of the contact elements with one another, rests on these several contact elements. By means of the busbars, the energy absorbed by the respective contact elements is collected and directed to terminals to which the power is provided. If the application of the at least one busbar occurs directly after step c), a secure electrical contact between busbar and contact element is thus ensured. If, however, the application of the busbar occurs after step d), the electrical contact is thus influenced by the previously applied or deposited nitride layer.

It is therefore preferably provided that, for electrical connection of the busbar with the several contact elements, the entire solar cell with the emitter structure is heated, in particular sintered, for so-called through-firing. Such a high temperature is generated thereby, which ensures that the busbar burns through the nitride layer and reaches the contact elements, whereby a reliable electrical connection is ensured.

According to an advantageous development of the invention, it is provided that the production of the contact elements in step b) is carried out by a screen printing method. In particular, a screen printing method is provided in which a silver paste is applied as mentioned above. After the printing of the contact elements or contact fingers, the paste is preferably dried and optionally burned out. Then, still before step c), a sintering step of the contact elements preferably follows in order to solidify the structure thereof. The sintering step may, however, also occur later. In this context, the sintering step is preferably performed in the above-mentioned through-firing. The contact elements or contact fingers preferably have a height of approximately 10 μm, while the emitter etching depth is preferably provided to be 50 to 100 nm.

It is particularly preferably provided that the emitter layer of the solar cell or the wafer is doped in step a) with phosphorus or boron. Of course, it is also conceivable to provide the emitter layer with other dopants or designs which are suitable for solar cells. Here, a person of ordinary skill in the art can select a suitable doping for the desired area of application.

Furthermore, a device is proposed. In this case, the device has a printing device for producing the contact elements on the emitter layer of the solar cell, as well as an etching device for reducing the doping in the emitter layer. According to the invention, the printing device is arranged before the etching device, so that the solar cell provided with contact elements is subjected to a reduction of the doping in the emitter layer in the region between the contact elements by means of etching processing of the entire useful side of the solar cell. The aforementioned advantages result in this way.

Furthermore, the object of the invention is achieved by means of a solar cell having the features of claim 6. This is distinguished in that at least the entire useful side with the contact elements located thereon is etched to reduce the doping in the region between the contact elements. Due to the occurrence of etching on the outside of the contact elements, the contact elements will be regarded again later, as they serve as an etching mask for the generation of the selective emitter structure. Hereby arise the aforementioned advantages with regard to the automatic adjustment of the regions with high doping to the contact elements.

It is provided according to the invention that the useful side of the solar cell is provided with contact elements having a nitride layer. The nitride layer is preferably designed as a silicon nitride layer and serves as an anti-reflection layer which enables a higher energy yield of the solar rays which later strike the solar cell. As the nitride layer is only applied after the application of the contact elements, the nitride layer is also located on the contact elements such that the contact elements are electrically contactable without further intervention. It is therefore provided according to the invention that a so-called busbar lies on at least some of the contact elements, the busbar electrically connecting the several contact elements with one another. So that electrical contact with the busbar is produced, this is burned through by the nitride layer, as described above. Of course, it would also be alternatively conceivable in place of burning through to carry out a selective removal of the nitride layer on the contact elements before the application of the busbar.

The invention will hereafter be described in greater detail with reference to drawings.

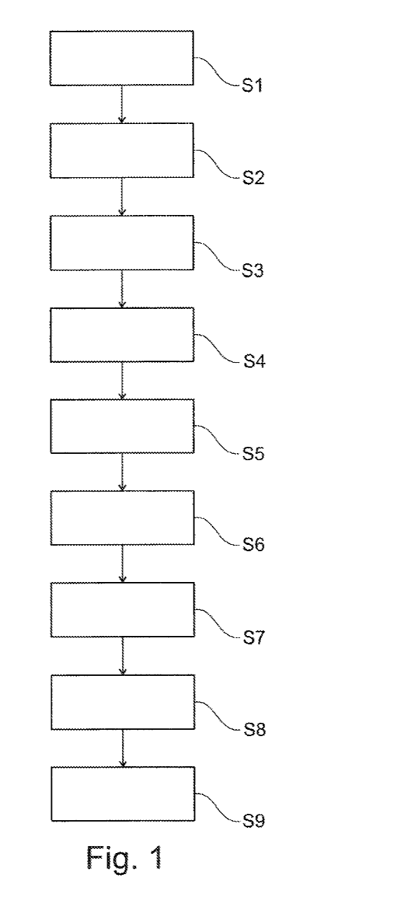

FIG. 1 shows a method for producing a selective emitter structure as a flow chart, and

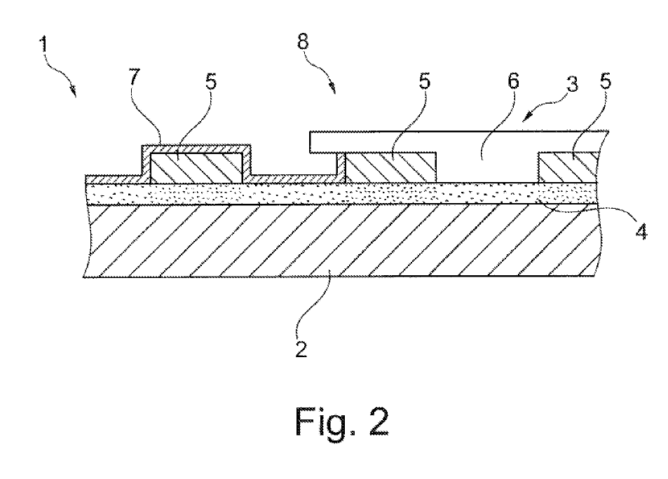

FIG. 2 shows a solar cell produced by the method in a simplified sectional view.

FIG. 1 shows a method for producing a selective emitter structure for solar cells by means of a flow chart. Step S1 takes as a starting point a prepared crystalline silicon wafer, which forms the basis for the finished solar cell. The wafer has a useful side and a back side, wherein the processing of the back side may take place in a manner known from the prior art, such as by means of application of a full-area metal contact. The method presented here relates solely to an advantageous production and refinement of the useful side.

In a second step S2, an emitter layer is formed on the wafer, preferably by placing the wafer in a phosphorus- and oxygen-containing atmosphere in which the phosphorus is diffused into the wafer, thereby producing a doped emitter layer. Optionally, phosphorus glass is thereby formed on the surface of the wafer. Typically, the diffusing is carried out such that the wafer is provided completely, i.e. on all sides, with the doped emitter layer. The treatment of the wafer is preferably performed such that the emitter layer has a desired level of doping, which will later be located below the contact elements of the solar cell.

In a subsequent step S3, the backside of the wafer is preferably wet-chemically treated, in particular by etching, to remove the emitter layer formed on the back, so that short circuits in the solar cell can be avoided. The phosphorus glass is then optionally also preferably removed again from the useful side of the wafer or the solar cell by means of chemical treatment.

Thereafter in a step S4, a plurality of contact elements are applied on the useful side of the solar cell in the form of contact fingers which extend effectively parallel to one another, preferably across the total surface of the solar cell. The contact fingers thus lie atop the highly doped emitter layer. The contact fingers preferably have a width of 50 to 90 μm, in particular 70 μm. The contact fingers especially preferably additionally have a thickness or height of 8 to 12 μm, in particular 10 μm.

Then in a step S5, the entire useful side of the wafer or of the solar cell undergoes an etching processing in a step S6. By means of wet-chemical etching, plasma etching or by means of etching gases, the doping of the emitter layer is thereby reduced where the etching medium reaches the emitter layer. The contact fingers act as an etching mask on the emitter layer, so that the doping of the emitter layer is reduced only in regions between the contact fingers, while the high doping remains beneath the contact fingers. It is preferably thereby provided that the etching process achieves etching depths of 50 to 100 nm in the emitter layer.

Then in a step S7, the useful side is provided with a nitride layer, which is appropriately carried out by nitride deposition. Here also, the contact fingers are covered by the nitride layer. The nitride layer may, for example, achieve a thickness of 70 to 100 nm.

Then in a step S8, one or more busbars are produced which lie on the contact fingers, in order to electrically connect the contact fingers with one another. Due to the interposed nitride layer, the electrical contact between the contact fingers and the busbar cannot be ensured.

Therefore in a subsequent step S9, the solar cell is heated as a whole, in particular sintered, so that a so-called through-firing occurs, in which the busbars burn through the nitride layer and reach the contact fingers, whereby the electrical contact to the contact fingers can be produced and ensured.

The presented method has the advantage that the contact fingers themselves serve as an etching mask and an adjustment between the generated high doped and low doped regions of the emitter layer and the application of the contact fingers is eliminated. The manufacturing process can thus be simplified and sources of failure eliminated, while simultaneously optimally utilizing the efficiency of the solar cell. In particular, the overdimensioning of highly doped regions for reasons of tolerance need hereby no longer be provided. Appropriately here, the process control during the etching is selected such that the contact fingers are only minimally etched and the etching depth for the emitter layer and the emitter is sufficient. For etching could be used, for example, plasma excitation with halogen gas mixtures. NF3-Ar mixtures, for example, ensure that no non-volatile etching residues remain on the contact fingers. Further could be used for the etching step silicon etching gases such as ClF3 without plasma exposure. Depending on the process control, non-volatile silver-oxygen compounds could remain on the surface of the contact fingers or be removed in situ.

FIG. 2 shows a solar cell 1, prepared by the method described above. The solar cell 1 has a crystalline silicon wafer 2, on the useful side 3 of which is formed an emitter layer 4. A plurality of contact fingers 5 lie on the useful side 3 of the emitter layer in the form of contact fingers which extend parallel to one another across the wafer 2 and the solar cell 1. In the section shown, the solar cell 1 further has a busbar 6 which lies on several contact elements 5, in order to electrically connect these with one another.

Of course, a plurality of busbars 6 may also be provided.

As described above, the emitter layer 4 is provided with a doping, in particular phosphorus doping, which has a higher doping in the regions below the contact elements 5 and a lower doping in the regions between the contact elements 5, as is indicated by the schematic dotting in FIG. 2. The doping is preferably a phosphorus or boron doping. By means of the etching processing of the useful side 3 after the application of the contact elements 5 on the emitter layer 4, the doping of the emitter layer 4 is reduced in the regions between the contact elements 5, as described above.

Furthermore, the solar cell 1 has a nitride layer 7, which extends over the entire useful side 3 on which the contact elements 5 are located. The busbar lies directly on the contact elements 5, as the busbar 6 is burned through the nitride layer 7, as described above, in order to produce the electrical contact to the contact element 5. The emitter layer 4, the contact elements 5 and the busbar 6 together form the selective emitter structure 8 of solar cell 1.

The advantageous emitter structure 8 has a particularly high efficiency, as the regions with higher doping are exactly aligned with the contact elements 5 and their widths are exactly adapted to the widths of the contact elements 5.

1. A method for producing a selective emitter structure (8) on a useful side (3) of a solar cell (1), wherein the emitter structure (8) comprises a doped emitter layer (4) and several contact elements (5), in particular contact fingers, arranged on the emitter layer (4), and wherein the emitter layer (4) is provided with higher doping in the region below the contact elements (5) than in the region between the contact elements (5), characterized by the following steps:
a) providing the solar cell (1) having an emitter layer (4) that is doped overall,
b) producing the contact elements (5) on the emitter layer (4), and
c) reducing the doping of the emitter layer (4) in the region between the contact elements (5) by an etching processing of the entire useful side (3) of the solar cell (1).

2. The method according to claim 1, characterized in that the etching is carried out wet-chemically by plasma exposure or etching gases.

3. The method according to any one of the preceding claims, characterized in that in particular the height of the contact elements (5) is selected depending on the desired reduction in the doping in the emitter layer (4).

4. The method according to any one of the preceding claims, characterized in that after step c) in a following step d) at least the useful side (3) of the solar cell (1) is provided with a nitride layer (7).

5. The method according to any one of the preceding claims, characterized in that the nitride layer (7) in step d) is produced by means of nitride deposition.

6. The method according to any one of the preceding claims, characterized in that after step d) or c) in a following step e) at least one busbar (6) is produced which, in order to electrically connect at least some of the contact elements (5) with one another, rests on these several contact elements (5).

7. The method according to any one of the preceding claims, characterized in that for electrical connection of the busbar (6) with the several contact elements (5), the solar cell (1) with the emitter structure is heated, in particular sintered, to so-called through-firing.

8. The method according to any one of the preceding claims, characterized in that the production of the contact elements (5) in step b) occurs by means of a screen printing method.

9. The method according to any one of the preceding claims, characterized in that the emitter layer (4) is doped with phosphorus or boron.

10. A device for producing a selective emitter structure (8) on a useful side (3) of a solar cell (1), wherein the emitter structure (8) comprises a doped emitter layer (4) and several contact elements (5), in particular contact fingers, arranged on the emitter layer (4), and wherein the emitter layer (4) is provided with higher doping in the region below the contact elements (5) than in the region between the contact elements (5), wherein the device has a printing device for producing the contact elements (5) and an etching device for at least selectively reducing the doping in the emitter layer (4), characterized in that for performing the method according to one or more of the claims 1 to 9, the printing device is arranged before the etching device.

11. A solar cell (1) having a selective emitter structure (8) on a useful side (3) of the solar cell (1), in particular produced by means of a method according to any one of claims 1 to 9 or by means of a device according to claim 10, wherein the emitter structure (8) comprises a doped emitter layer (4) and several contact elements (5), in particular contact fingers, arranged on the emitter layer (4), and wherein the emitter layer (4) is provided with higher doping in the region below the contact elements (5) than in the region between the contact elements (5), characterized in that the total useful side (3) of the solar cell (1) is etched at least to reduce the doping in the region between the contact elements (5).

12. The solar cell (1) according to claim 11, characterized in that the useful side (3) of the solar cell (1) having contact elements (5) is provided with a nitride layer (7).
